(19) United States
(12) Patent Application Publication
(10) Pub. No.: US 2026/0191051 A1
(43) Pub. Date: Jul. 2, 2026

(54) ELECTRONIC PACKAGE, SUBSTRATE STRUCTURE AND MANUFACTURING METHOD THEREOF

(71) Applicant: SILICONWARE PRECISION INDUSTRIES CO., LTD., Taichung City (TW)

(72) Inventors: Fu-Cheng KAO, Taichung City (TW); Kai-Lun LIANG, Taichung City (TW); Shu-Ting LAI, Taichung City (TW); Chun-Huan HUNG, Taichung City (TW); Cheng-Han YAO, Taichung City (TW); Chiu-Lien LI, Taichung City (TW)

(21) Appl. No.: 19/051,638

(22) Filed: Feb. 12, 2025

(30) Foreign Application Priority Data
Jan. 2, 2025 (TW) 114100144

(51) Int. Cl. H01L 23/498; H01L 21/48; H01L 23/00

(52) U.S. Cl. CPC H10W 70/65; H10W 99/00; H10W 70/60; H10W 72/072; H10W 72/241; H10W 90/724

(57) ABSTRACT

An electronic package, a substrate structure and a manufacturing method thereof are provided. An electronic component is disposed on the substrate structure having a plurality of electrical contact pads and a metal sheet by means of solder material. An insulating protective layer of the substrate structure has an opening exposing the plurality of electrical contact pads, the metal sheet is disposed at the periphery of the electrical contact pads, and a separation space is formed so as to reduce the amount of solder paste that spreads out of the solder material, so that the problem of short circuit caused by the expansion of the solder material can be prevented from occurring to each of the plurality of electrical contact pads.

### CROSS-REFERENCE TO RELATED APPLICATIONS

The present application is based upon and claims the right of priority to TW Patent Application No. 114100144, filed Jan. 2, 2025, the disclosure of which is hereby incorporated by reference herein in its entirety for all purposes

### BACKGROUND

### 1. Technical Field

The present disclosure relates to a semiconductor packaging technology, and more particularly, to a flip-chip electronic package and a substrate structure and a manufacturing method thereof.

### 2. Description of Related Art

With the development of the electronics industry, today's electronic products have been designed to be thin, light, short and compact with diversified functions. As a result, different packaging types have been developed with respect to the semiconductor packaging technology. In order to meet the needs of high integration and miniaturization of semiconductor devices, in addition to the traditional wire bonding of the semiconductor packaging technology, the flip-chip method can also be used to improve wiring density.

FIG. 1 is a schematic cross-sectional view of a conventional flip-chip semiconductor package 1. As shown in FIG. 1, an insulating protective layer 13 of a package substrate 10 is formed with a plurality of openings 130 corresponding to an exposed circuit layer 14, so that a semiconductor chip 11 is bonded to electrical contact pads 140 of the circuit layer 14 via the openings 130 by a plurality of solder bumps 110 to electrically connect conductive traces 141 of the circuit layer 14. Then, an underfill 12 is formed between the semiconductor chip 11 and the package substrate 10 to cover the solder bumps 110.

However, the circuit layer 14 of the conventional package substrate 10 is of the bump-on-trace (BOT) type. Therefore, when copper material (such as copper sheet or conductive trace 141) is placed around each electrical contact pad 140 to provide grounding, the solder paste of each solder bump 110 will spread outward. Accordingly, a short circuit is easily formed between the electrical contact pads 140, thereby resulting in a decrease in product yield.

Therefore, how to overcome the above-mentioned drawbacks of the prior art has become an urgent issue to be solved in the industry.

### SUMMARY

In view of the various deficiencies of the prior art, the present disclosure provides a substrate structure, which comprises: a substrate body having a plurality of electrical contact pads and a metal sheet, wherein a notch is formed on one side of the metal sheet, at least one of the plurality of electrical contact pads is located in the notch, two opposite ends of the at least one of the plurality of electrical contact pads are in contact with the metal sheet, and a separation space is formed between one side of the at least one of the plurality of electrical contact pads and the notch of the metal sheet; and an insulating protective layer formed on the substrate body and having an opening exposing the plurality of electrical contact pads.

The present disclosure also provides a method of manufacturing a substrate structure, the method comprises: providing a substrate body having a plurality of electrical contact pads and a metal sheet, wherein a notch is formed on one side of the metal sheet, at least one of the plurality of electrical contact pads is located in the notch, two opposite ends of the at least one of the plurality of electrical contact pads are in contact with the metal sheet, and a separation space is formed between one side of the at least one of the plurality of electrical contact pads and the notch of the metal sheet; and forming an insulating protective layer on the substrate body, wherein the insulating protective layer has an opening exposing the plurality of electrical contact pads.

In the aforementioned substrate structure and method, the substrate body has an insulating layer bonded to the plurality of electrical contact pads and the metal sheet.

In the aforementioned substrate structure and method, the two opposite ends of the at least one of the plurality of electrical contact pads are formed with extension sections, and the extension sections are embedded in the metal sheet.

In the aforementioned substrate structure and method, one of the two opposite ends of the at least one of the plurality of electrical contact pads is formed with an extension section, and the extension section is embedded in the metal sheet.

The present disclosure further provides an electronic package, which comprises: the aforementioned substrate structure; and an electronic component bonded and electrically connected to the plurality of electrical contact pads via a plurality of conductive bumps.

The present disclosure further provides a method of manufacturing an electronic package, the method comprises: providing the aforementioned substrate structure; and bonding an electronic component to the plurality of electrical contact pads via a plurality of conductive bumps, wherein the electronic component is electrically connected to the plurality of electrical contact pads.

In the aforementioned electronic package and method, each of the plurality of conductive bumps includes a solder material.

As can be seen from the above, in the electronic package and substrate structure and manufacturing method of the present disclosure, the metal sheet is disposed at the periphery of the electrical contact pads to reduce the amount of solder paste that spreads outward from the solder material. Therefore, compared with the prior art, the problem of short circuit caused by the expansion of the solder material can be prevented from occurring to each of the electrical contact pads of the electronic package of the present disclosure, so that the product yield can be improved.

### BRIEF DESCRIPTION OF THE DRAWINGS

FIG. 1 is a schematic cross-sectional view of a conventional semiconductor package.

FIG. 2A to FIG. 2C are schematic cross-sectional views illustrating a method of manufacturing an electronic package according to the present disclosure.

FIG. 3A is a partial top view of FIG. 2A.

FIG. 3B and FIG. 3C are partial top views according to other embodiments of FIG. 3A.

FIG. 4 is a partial top view of FIG. 2B.

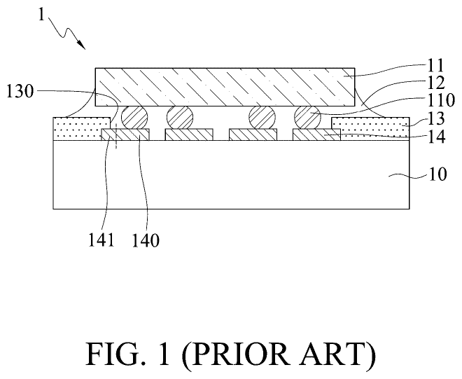

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

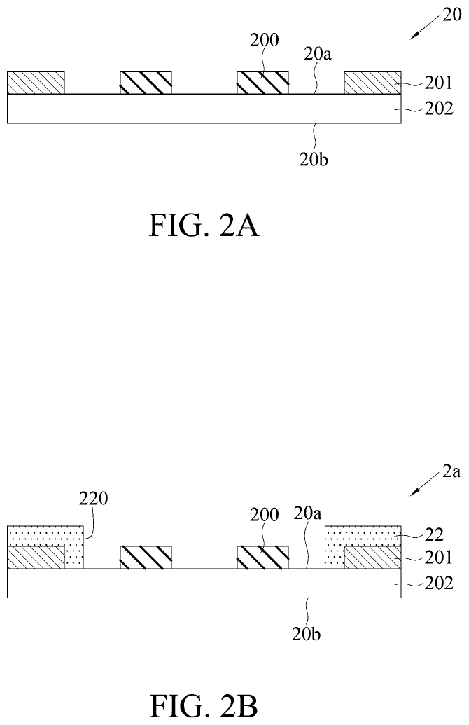

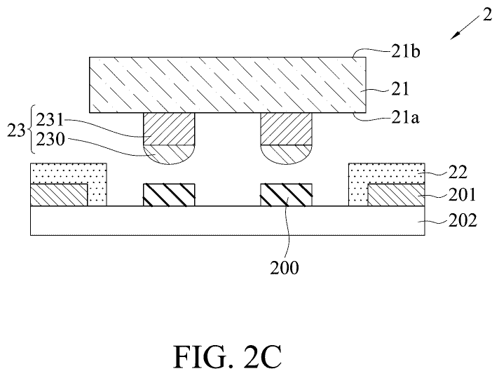

FIG. 2A to FIG. 2C are schematic cross-sectional views illustrating a method of manufacturing an electronic package 2 according to the present disclosure.

As shown in FIG. 2A and FIG. 2B, a substrate structure 2a is manufactured. First, a substrate body 20 is provided, and then an insulating protective layer 22 is formed on the substrate body 20.

The substrate body 20 has a first surface 20a and a second surface 20b opposite to the first surface 20a, and a plurality of electrical contact pads 200 and at least one metal sheet 201 are formed on the first surface 20a of the substrate body 20.

In one embodiment, the substrate body 20 is a package substrate having a core layer and a circuit structure, a package substrate having a coreless circuit structure, a through-silicon interposer (TSI) having conductive through-silicon vias (TSVs), or other board types.

Moreover, the substrate body 20 is formed by a redistribution layer (RDL) manufacturing method, wherein the substrate body 20 has at least one insulating layer 202 bonded to the plurality of electrical contact pads 200 and the metal sheet 201. For example, the metal sheet 201 and each of the electrical contact pads 200 are made of copper, and the insulating layer 202 is made of polybenzoxazole (PBO), polyimide (PI), prepreg (PP), or other dielectric materials.

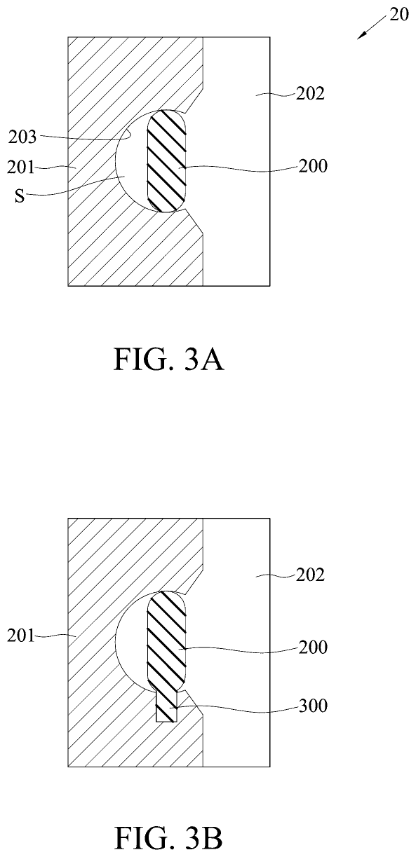

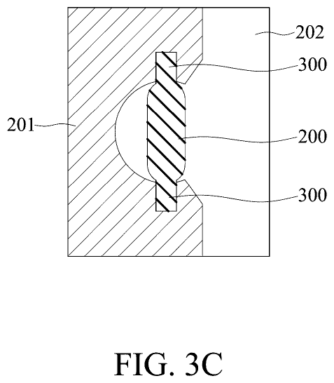

Furthermore, the metal sheet 201 is disposed at the periphery of the electrical contact pads 200, such as the upper, lower, and left sides as shown in FIG. 3A. A notch 203 is formed on one side of the metal sheet 201 so that at least one of the electrical contact pads 200 is located in the notch 203. The two opposite ends of the electrical contact pad 200 (the upper and lower sides as shown in FIG. 3A) are in contact with the metal sheet 201, so that a separation space S is formed between one side of the electrical contact pad 200 and the notch 203 of the metal sheet 201.

In addition, at least one of the two opposite ends of the electrical contact pad 200 can be formed with an extension section 300 to be embedded in the metal sheet 201. As shown in FIG. 3B, one end of the electrical contact pad 200 is embedded in the metal sheet 201, or as shown in FIG. 3C, both ends of the electrical contact pad 200 are embedded in the metal sheet 201.

In one embodiment, the edge of the electrical contact pad 200 is not connected to a conductive trace or other circuit form, so the extension section 300 is a part of the electrical contact pad 200 rather than a conductive trace or circuit form. In one embodiment, the electrical contact pad 200 is in the form of a bump-on-trace (BOT).

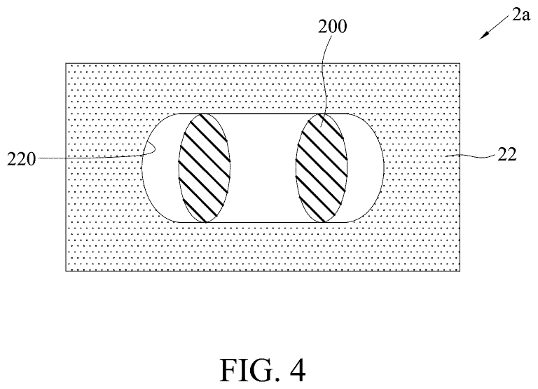

The insulating protective layer 22 is used as a solder mask layer and is made of solder resist material or graphite, wherein the insulating protective layer 22 is formed on the first surface 20a of the substrate body 20 and encapsulates the metal sheet 201, and the insulating protective layer 22 is formed with an opening 220 exposing the plurality of electrical contact pads 200, as shown in FIG. 4.

As shown in FIG. 2C, an electronic component 21 is bonded to the plurality of electrical contact pads 200 via a plurality of conductive bumps 23.

The electronic component 21 is an active component, a passive component, or a combination of the active component and the passive component, wherein the active component is, for example, a semiconductor chip, and the passive component is, for example, a resistor, a capacitor, or an inductor.

In one embodiment, the electronic component 21 is a semiconductor chip, wherein the electronic component 21 has an active surface 21a and an inactive surface 21b opposite to the active surface 21a, and the active surface 21a of the electronic component 21 is bonded to the conductive bumps 23.

Furthermore, each of the conductive bumps 23 includes a solder material 230 such as solder paste. For example, each of the conductive bumps 23 has a metal pillar 231 (such as a copper pillar) for bonding to the active surface 21a of the electronic component 21, and the solder material 230 is formed on the metal pillar 231, so that the electronic component 21 is disposed on the plurality of electrical contact pads 200 by a flip-chip method.

Therefore, in the manufacturing method of the electronic package 2 of the present disclosure, the metal sheet 201 of the substrate body 20 of the substrate structure 2a is disposed at the periphery of the electrical contact pads 200, so that the separation space S is formed between at least one of the electrical contact pads 200 and the metal sheet 201. Accordingly, the amount of solder paste that spreads out of the solder material 230 can be reduced via the separation space S when bonding the solder material 230. Therefore, compared with the prior art, the electronic package 2 of the present disclosure can prevent the solder material 230 from diffusing to other areas, thereby preventing the short circuit problem from occurring between the electrical contact pads 200.

The present disclosure also provides a substrate structure 2a, which comprises: a substrate body 20, and an insulating protective layer 22 formed on the substrate body 20.

The substrate body 20 has a plurality of electrical contact pads 200 and at least one metal sheet 201, wherein the metal sheet 201 is disposed at the periphery of the electrical contact pads 200, wherein a notch 203 is formed on one side of the metal sheet 201, at least one of the plurality of electrical contact pads 200 is located in the notch 203, two opposite ends of the at least one of the plurality of electrical contact pads 200 are in contact with the metal sheet 201, and a separation space S is formed between one side of the at least one of the plurality of electrical contact pads 200 and the notch 203 of the metal sheet 201.

The insulating protective layer 22 is formed on the substrate body 20 and has an opening 220 exposing the plurality of electrical contact pads 200.

In one embodiment, the substrate body 20 has an insulating layer 202 bonded to the plurality of electrical contact pads 200 and the metal sheet 201.

In one embodiment, the two opposite ends of the at least one of the plurality of electrical contact pads 200 are formed with extension sections 300, and the extension sections 300 are embedded in the metal sheet 201.

In one embodiment, one of the two opposite ends of the at least one of the plurality of electrical contact pads 200 is formed with an extension section 300, and the extension section 300 is embedded in the metal sheet 201.

The present disclosure also provides an electronic package 2, which comprises: the substrate structure 2a, and at least one electronic component 21 disposed on the substrate structure 2a.

The electronic component 21 is bonded to the plurality of electrical contact pads 200 via conductive bumps 23 and is electrically connected to the plurality of electrical contact pads 200.

In one embodiment, each of the conductive bumps 23 includes a solder material 230.

In summary, in the electronic package and substrate structure and manufacturing method of the present disclosure, the metal sheet is disposed at the periphery of the electrical contact pads to reduce the amount of solder paste that spreads outward from the solder material. Therefore, the problem of short circuit caused by the expansion of the solder material can be prevented from occurring to each of the electrical contact pads of the electronic package of the present disclosure, so that the product yield can be improved.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
a substrate body having a plurality of electrical contact pads and a metal sheet, wherein a notch is formed on one side of the metal sheet, at least one of the plurality of electrical contact pads is located in the notch, two opposite ends of the at least one of the plurality of electrical contact pads are in contact with the metal sheet, and a separation space is formed between one side of the at least one of the plurality of electrical contact pads and the notch of the metal sheet; and
an insulating protective layer formed on the substrate body and having an opening exposing the plurality of electrical contact pads.

2. The substrate structure of claim 1, wherein the substrate body further has an insulating layer formed on the plurality of electrical contact pads and the metal sheet.

3. The substrate structure of claim 1, wherein the two opposite ends of the at least one of the plurality of electrical contact pads are formed with extension sections, and the extension sections are embedded in the metal sheet.

4. The substrate structure of claim 1, wherein one of the two opposite ends of the at least one of the plurality of electrical contact pads is formed with an extension section, and the extension section is embedded in the metal sheet.

5. An electronic package, comprising:
the substrate structure of claim 1; and
an electronic component bonded and electrically connected to the plurality of electrical contact pads via a plurality of conductive bumps.

6. The electronic package of claim 5, wherein each of the plurality of conductive bumps includes a solder material.

7. An electronic package, comprising:
the substrate structure of claim 2; and
an electronic component bonded and electrically connected to the plurality of electrical contact pads via a plurality of conductive bumps.

8. The electronic package of claim 7, wherein each of the plurality of conductive bumps includes a solder material.

9. An electronic package, comprising:
the substrate structure of claim 3; and
an electronic component bonded and electrically connected to the plurality of electrical contact pads via a plurality of conductive bumps.

10. The electronic package of claim 9, wherein each of the plurality of conductive bumps includes a solder material.

11. An electronic package, comprising:
the substrate structure of claim 4; and
an electronic component bonded and electrically connected to the plurality of electrical contact pads via a plurality of conductive bumps.

12. The electronic package of claim 11, wherein each of the plurality of conductive bumps includes a solder material.

13. A method of manufacturing a substrate structure, comprising:
providing a substrate body having a plurality of electrical contact pads and a metal sheet, wherein a notch is formed on one side of the metal sheet, at least one of the plurality of electrical contact pads is located in the notch, two opposite ends of the at least one of the plurality of electrical contact pads are in contact with the metal sheet, and a separation space is formed between one side of the at least one of the plurality of electrical contact pads and the notch of the metal sheet; and
forming an insulating protective layer on the substrate body, wherein the insulating protective layer has an opening for exposing the plurality of electrical contact pads.

14. The method of claim 13, wherein the substrate body further has an insulating layer formed on the plurality of electrical contact pads and the metal sheet.

15. The method of claim 13, wherein the two opposite ends of the at least one of the plurality of electrical contact pads are formed with extension sections, and the extension sections are embedded in the metal sheet.

16. The method of claim 13, wherein one of the two opposite ends of the at least one of the plurality of electrical contact pads is formed with an extension section, and the extension section is embedded in the metal sheet.

17. A method of manufacturing an electronic package, comprising:
providing the substrate structure of claim 1; and
bonding an electronic component to the plurality of electrical contact pads via a plurality of conductive bumps, wherein the electronic component is electrically connected to the plurality of electrical contact pads.

18. The method of claim 17, wherein each of the plurality of conductive bumps includes a solder material.

19. A method of manufacturing an electronic package, comprising:
providing the substrate structure of claim 2; and
bonding an electronic component to the plurality of electrical contact pads via a plurality of conductive bumps, wherein the electronic component is electrically connected to the plurality of electrical contact pads.

20. The method of claim 19, wherein each of the plurality of conductive bumps includes a solder material.

21. A method of manufacturing an electronic package, comprising:
providing the substrate structure of claim 3; and
bonding an electronic component to the plurality of electrical contact pads via a plurality of conductive bumps, wherein the electronic component is electrically connected to the plurality of electrical contact pads.

22. The method of claim 21, wherein each of the plurality of conductive bumps includes a solder material.

23. A method of manufacturing an electronic package, comprising:
providing the substrate structure of claim 4; and
bonding an electronic component to the plurality of electrical contact pads via a plurality of conductive bumps, wherein the electronic component is electrically connected to the plurality of electrical contact pads.

24. The method of claim 23, wherein each of the plurality of conductive bumps includes a solder material.
